(19) United States
(12) Patent Application Publication
(10) Pub. No.: US 2009/0032089 A1
(43) Pub. Date: Feb. 5, 2009

(54) Solar tracker having louver frames

(75) Inventors: Wen-Fu Chen, Banqiao City (TW); Cheng-Chao Huang, Fenglin Town (TW); Cheng-Dar Lee, Tainan City (TW)

Correspondence Address: TROXELL LAW OFFICE PLLC, 5205 LEESBURG PIKE, SUITE 1404, FALLS CHURCH, VA, 22041, US

(73) Assignee: ATOMIC ENERGY COUNCIL - INSTITUTE OF NUCLEAR ENERGY RESEARCH, Taoyuan (TW)

(21) Appl. No.: 11/882,622

(22) Filed: Aug. 3, 2007

(51) Int. Cl. H01L 31/048

(52) U.S. Cl. 136/251; 136/246

(57) ABSTRACT

A solar tracker does not need to stand high. The solar tracker has a strong structure and a stable center of gravity for tracking sunlight. Thus, the solar tracker does not need a foundation to be connected for standing upon. And the solar tracker is fit to be used on a bare ground or roof with a low cost.

### FIELD OF THE INVENTION

The present invention relates to a solar tracker; more particularly, relates to greatly reducing a vertical height required for a solar tracker and to reinforcing a whole structure of the solar tracker to avoid building a foundation and thus become fitful to be used on a bare ground or roof with a low cost.

### DESCRIPTION OF THE RELATED ART

In the past, a general solar tracker requires a foundation having a hollow-pipe support which has an insert at an upper end to be fixed at bottom of the solar tracker and a plurality of solar cell modules for supporting. Although the foundation supports the solar tracker and the solar cell modules, time, space and cost are required for setting the foundation with the hollow-pipe support, and the building process is not fit for roof. Hence, the prior art does not fulfill all users' requests on actual use.

### SUMMARY OF THE INVENTION

The main purpose of the present invention is to carry III-V high concentration photovoltaics (HCPV) modules with sunlight tracked for reception for more power to be generated.

Another purpose of the present invention is to greatly reduce a vertical height required for a solar tracker by using an azimuth and elevation mode design.

A third purpose of the present invention is to reinforce a whole structure of a solar tracker by using an azimuth device, a round track of chassis and a plurality of support wheels so that a foundation usually required is saved and thus the solar tracker is fit to be used on a bare ground or roof with a low cost.

To achieve the above purpose, the present invention is a solar tracker having louver frames comprising three solar cell module frames, an elevation actuator, three elevation cross beams, two parallel connecting rods, a support structure, a motorgear reducer and worm gear set, a support axle and bearing set and a regular seat, where each solar cell module frame carries 16 solar cell modules and generates 110 watts power; the solar cell module frame is moved by the elevation actuator to make an elevation motion at an angle between 0 and 80 degrees; the elevation crossbeam is connected to the support structure with bearings separately at two ends for the elevation motion of the solar cell module frame; the parallel connecting rods are separately fixed at inner sides next to the bearings of the elevation crossbeam; the elevation actuator moves one of the parallel connecting rods for the elevation motion of the solar cell module frame; there are six support wheels underneath the support structure; and the regular seat has four extension feet connected with a round track for the support wheels of the support structure to walk on. Accordingly, a novel solar tracker having louver frames is obtained.

### BRIEF DESCRIPTION OF THE DRAWINGS

The present invention will be better understood from the following detailed description of the preferred embodiment according to the present invention, taken in con junction with the accompanying drawings, in which

FIG. 1 is the perspective view showing the preferred embodiment according to the present invention;

FIG. 2 is the front view showing the preferred embodiment;

FIG. 3 is the top-down view showing the preferred embodiment;

FIG. 4 is the side view showing the preferred embodiment;

FIG. 5 is the perspective view showing the upper part structure;

FIG. 6 is the perspective view showing the lower part structure;

FIG. 7 is the view showing the solar cell module frame;

FIG. 8 is the view showing the elevation actuator;

FIG. 9 is the view showing the elevation crossbeam;

FIG. 10 is the detail view showing the ‘A’ in FIG. 9;

FIG. 11 is the view showing the parallel connecting rod;

FIG. 12 is the view showing the support structure;

FIG. 13 is the view showing the motorgear reducer and worm gear set;

FIG. 14 is the view showing the support axle and bearing set; and

FIG. 15 is the view showing the regular seat.

### DESCRIPTION OF THE PREFERRED EMBODIMENT

The following description of the preferred embodiment is provided to understand the features and the structures of the present invention.

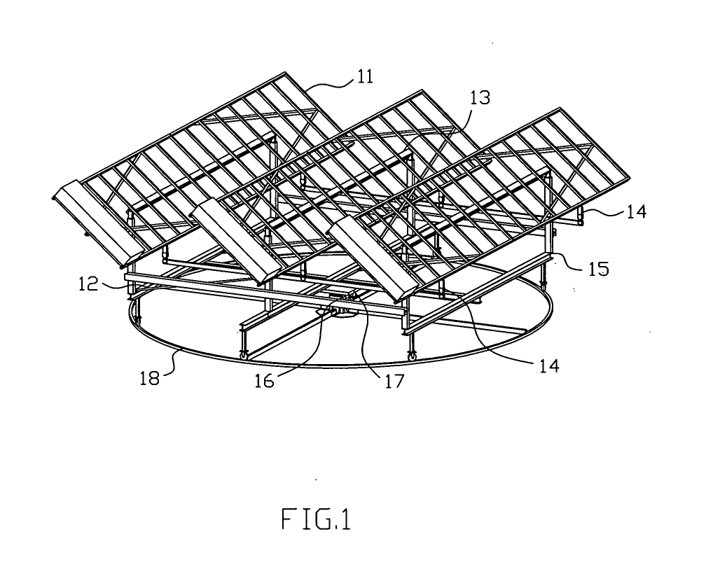

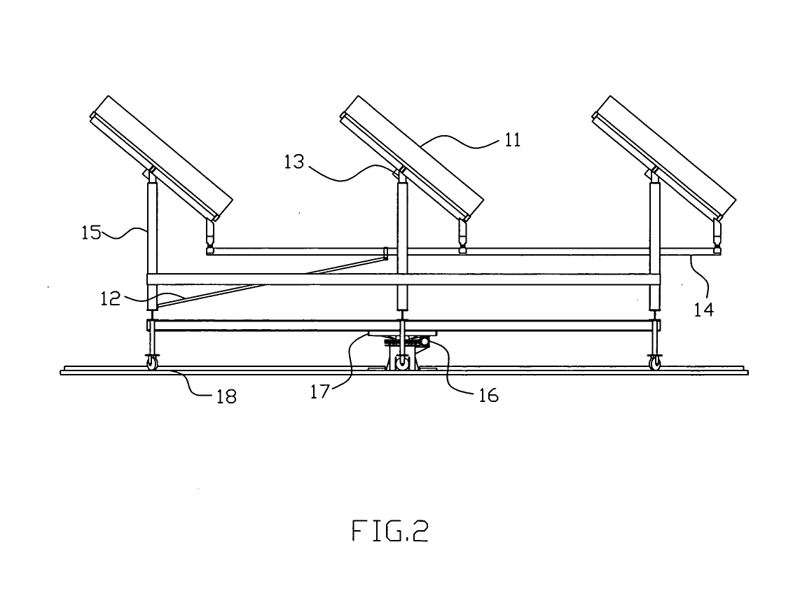

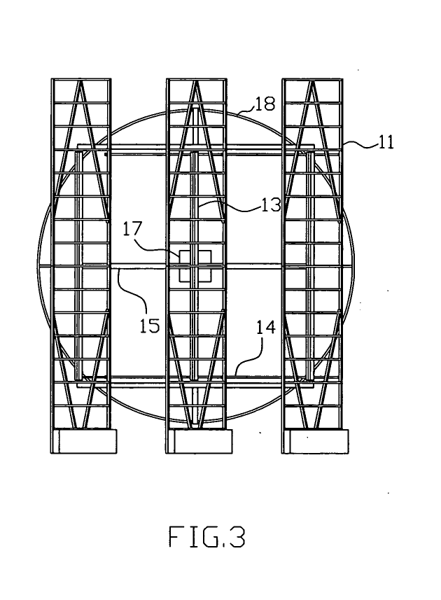

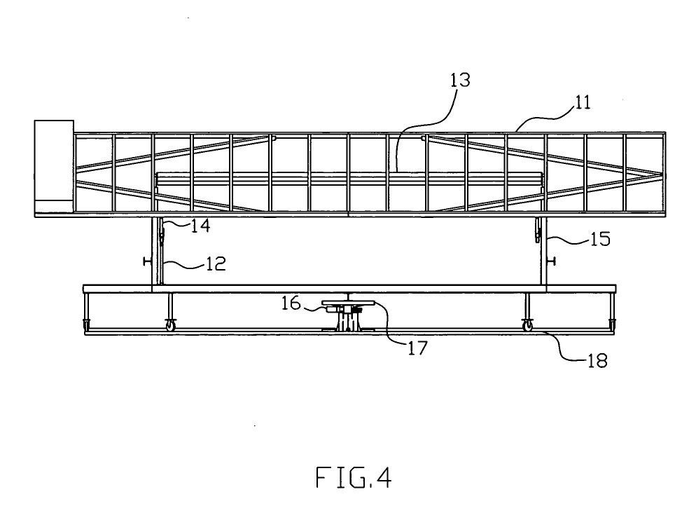

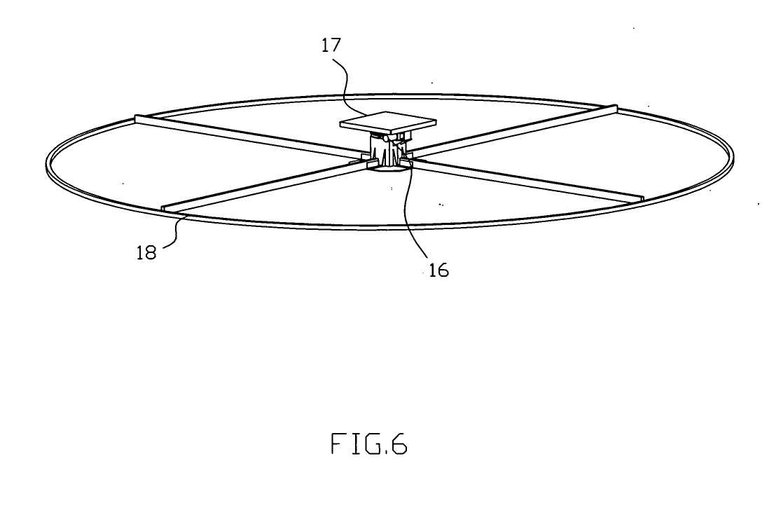

Please refer to FIG. 1 to FIG. 6, which is a perspective view, a front view, a top-down view and a side view showing a preferred embodiment according to the present invention; and perspective views showing an upper part structure and a lower part structure. As shown in the figures, the present invention is a solar tracker having louver frames, comprising three solar cell module frames [11], an elevation actuator [12], three elevation crossbeams [13], two parallel connecting rods [14], a support structure [15], a motorgear reducer and worm gear set [16], a support axle and bearing set [17] and a regular seat [18], where III-V high concentration photovoltaics (HCPV) modules are carried with sunlight tracked for reception for more power to be generated.

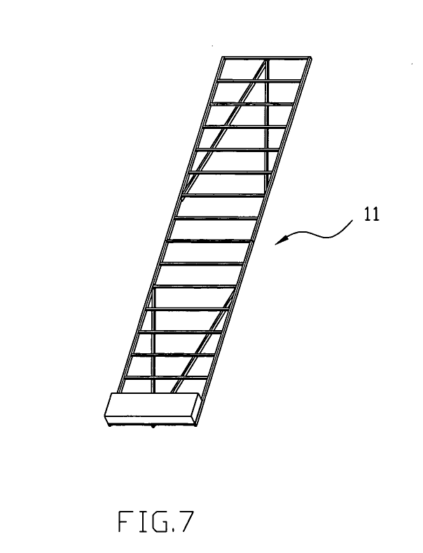

Please further refer to FIG. 7, which is a view showing a solar cell module frame. As shown in the figure, a solar cell module frame [11] carries 16 solar cell modules (not shown in the figure); and, hence, three solar cell module frames [11] totally carry 48 solar cell modules. The solar cell module [11] generates 110 watts (W) power; and, hence, three solar cell module frames [11] totally generate 5.2 kilo-watts (kW) power.

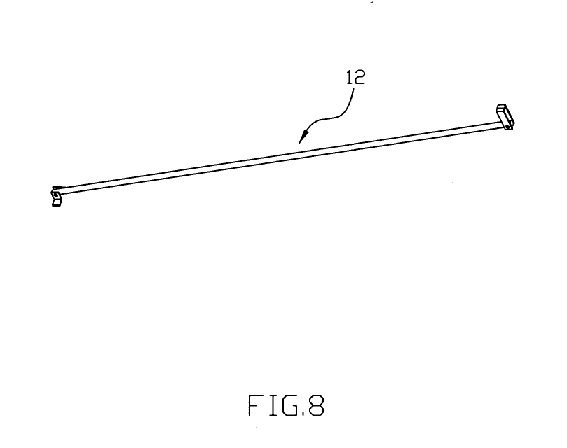

Please further refer to FIG. 8, which is a view showing an elevation actuator. As shown in the figure, an elevation actuator [12] elevates the solar cell module frame [11], where the elevation actuator [12] moves the solar cell module frame [11] at a horizontal contained angle between 0 and 80 degrees.

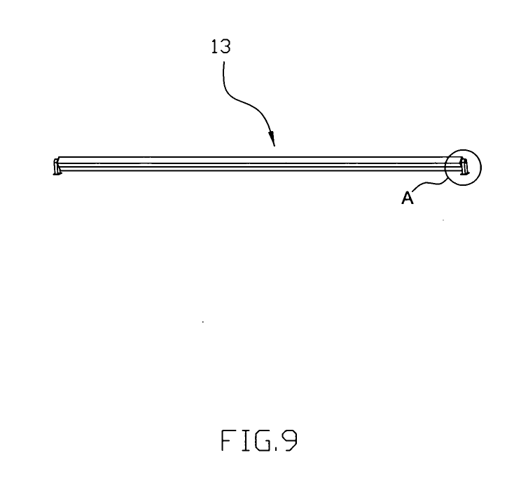

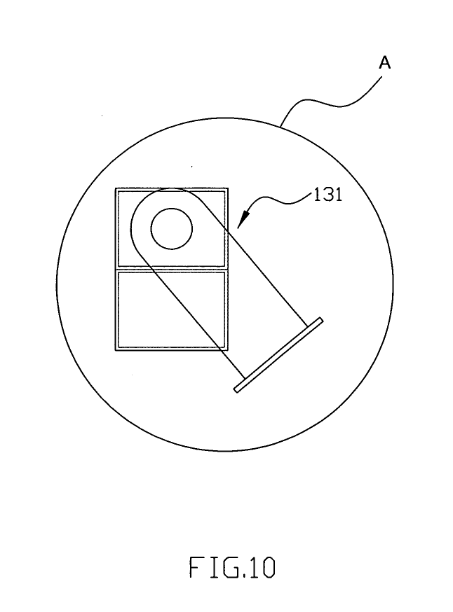

Please further refer to FIG. 9 and FIG. 10, which are a view showing a n elevation crossbeam and a detail view showing ‘A’ in FIG. 9. As shown in the figures, an elevation crossbeam [13] is used to support the solar cell module frame [11]. The elevation crossbeam [13] is connected to the support structure [15] with a bearing [131] at each of two ends so that the solar cell module frame [11] is carried to be elevated. Therein, there are three sets of the elevation crossbeam [13] which separately support three solar cell module frames [11] with each carrying 16 solar cell modules.

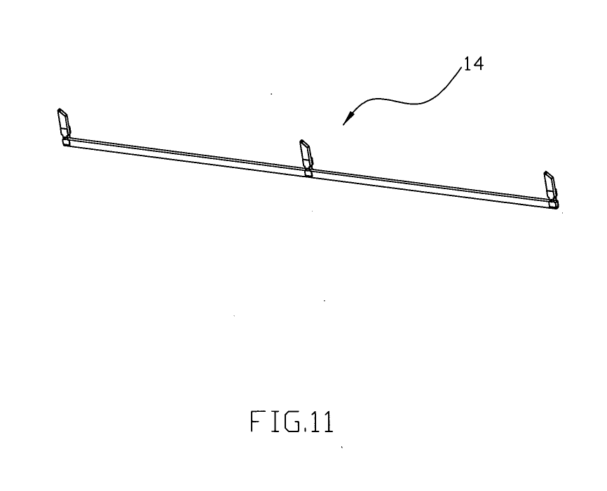

Please further refer to FIG. 11, which is a view showing a parallel connecting rod. As shown in the figure, a parallel connecting rod [14] is connected to three solar cell module frames [11] simultaneously at a side. And there are two parallel connecting rods [14] fixed at inner sides separately next to the bearings [131] of the elevation cross beams [13], where the elevation actuator [12] moves one of the parallel connecting rods [14] for an elevation motion of the solar cell module frame [11].

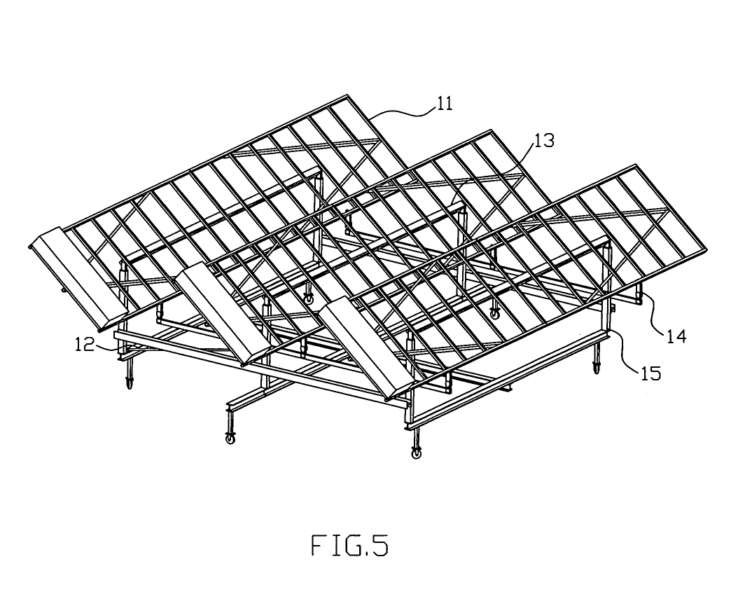

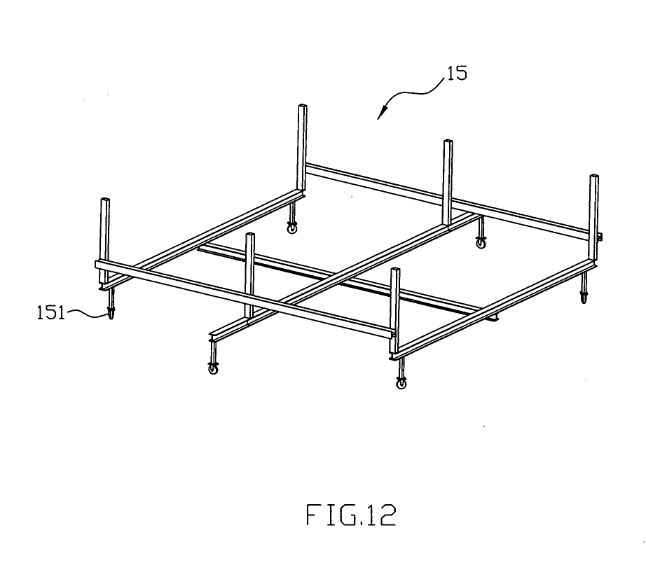

Please further refer to FIG. 12, which is a view showing a support structure. As shown in the figure, a support structure [15] supports the solar cell module frames [11], the elevation actuator [12], the elevation crossbeams [13] and the parallel connecting rods [14], where deformations of the solar cell module frames [11] are reduced. There are six support wheels [151] underneath the support structure [15] to directly support a weight of the support structure [15] together with what it carries by a round track below; and, so, an upper structure (as shown in FIG. 5) is reinforced and sunlight is tracked with an improved accuracy.

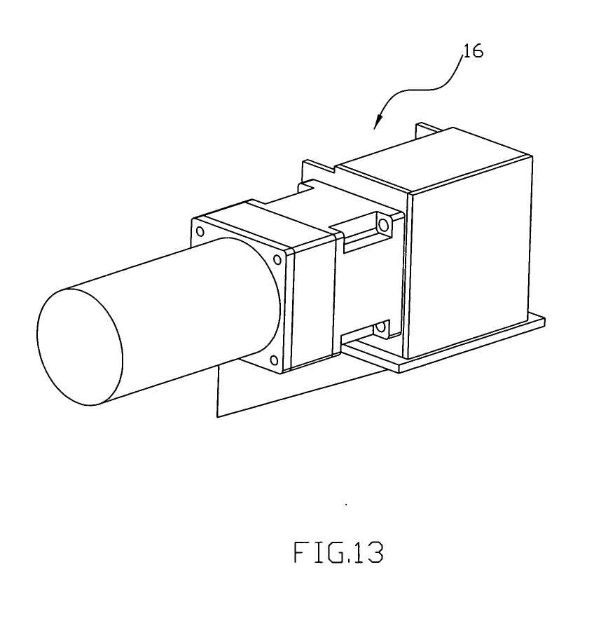

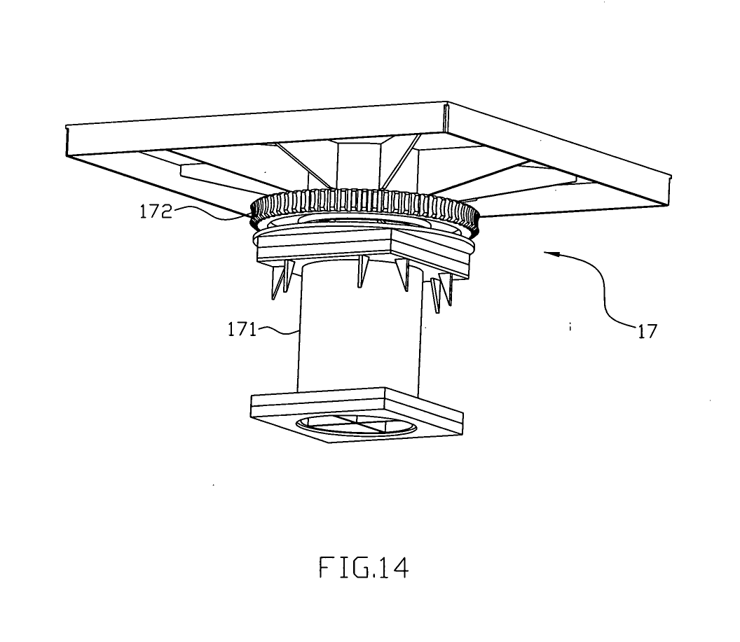

Please further refer to FIG. 13, which is a view showing a motor gear reducer and worm gear set. As shown in the figure, a motorgear reducer and worm gear set [16] drives a worm wheel [172] (as shown in FIG. 14) of the support axle and bearing set [17] for an azimuth motion.

Please further refer to FIG. 14, which is a view showing a support axle and bearing set. As shown in the figure, a support axle and bearing set [17] supports the support structure [15] and lays a weight of the support structure [15] on a support axle [171]. And, as is stated above, the support axle and bearing set [17] is moved by the motorgear reducer and worm gear set [16] through the worm wheel [172] for an azimuth motion.

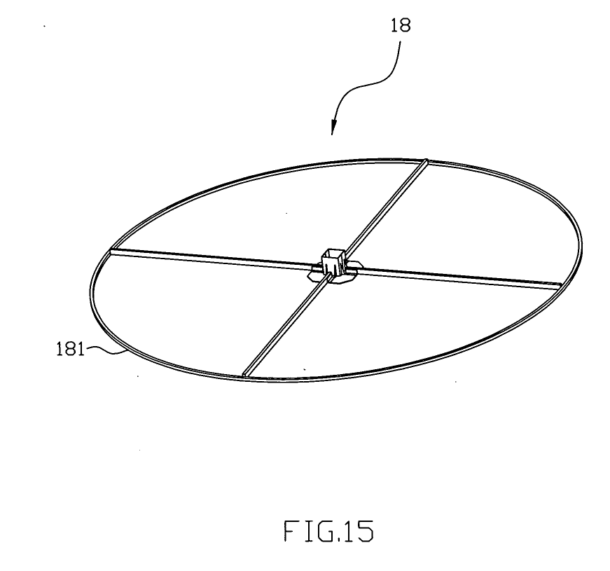

Please further refer to FIG. 15, which is a view showing a regular seat. As shown in the figure, a regular seat [18] transfers a weight of the support structure [15] together with that of the support axle and bearing set [17] to a ground or a roof. The regular seat [18] has four extension feet connected with a round track [181] for the support wheels [151] of the support structure [15] to walk on; and thus the present invention obtains a stable center of gravity.

When using the present invention, the three solar cell module frames [11] carrying the solar cell modules make an elevation motion through the parallel connecting rod [14]; the support structure [15] supporting the solar cell module frames [11] makes an azimuth motion by using the motorgear reducer and worm gear set [16]; the structure of the present invention is reinforced by using the support wheel [151] and the round track [181]; and, thus, with the above structure, the present invention tracks sunlight for reception to have more power generated

To sum up, the present invention is a solar tracker having louver frames, where III-V HCPV modules are carried with sunlight tracked without building a foundation and thus is fit to be used on a bare ground or roof with a low cost.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A solar tracker having louver frames, comprising:
three solar cell module frames, said solar cell module frame having solar cell modules deposed on said solar cell module frame;
an elevation actuator, said elevation actuator elevating said solar cell module frame;
three elevation crossbeams, said elevation crossbeam support said solar cell module frame on being elevated by said elevation actuator;
two parallel connecting rods, said parallel connecting rods being connected at a side of said solar cell module frames to elevate said solar cell module frames simultaneously;
a support structure said support structure supporting said solar cell module frame, said elevation actuator, said elevation crossbeam and said parallel connecting rod;
a motorgear reducer and worm gear set, said motorgear reducer and worm gear set obtaining an azimuth motion of said solar tracker;
a support axle and bearing set, said support axle and bearing set supporting said support structure to lay a weight of said support structure on a support axle; and
a regular seat, said regular seat transferring said weight of said support structure to a structure selected from a group con si sting of a ground and a roof.

2. The solar tracker according to claim 1,
wherein 16 solar cell modules are deposed on said solar cell module frame.

3. The solar tracker according to claim 2,
wherein said solar cell module generates 110 watts of power.

4. The solar tracker according to claim 1,
wherein said elevation actuator moves said solar cell module frame at a horizontal contained angle between 0 and 80 degrees.

5. The solar tracker according to claim 1,
wherein said elevation crossbeam connects to said support structure with a bearing at each of two ends of said elevation cross beam.

6. The solar tracker according to claim 1,
wherein said parallel connecting rod is fixed at a side next to a bearing of said elevation crossbeam to be moved by said elevation actuator.

7. The solar tracker according to claim 1,
wherein said support structure has six support wheels; and
wherein said weight of said support structure is directly supported by a round track under said support structure.

8. The solar tracker according to claim 1,
wherein said motorgear reducer and worm gear set drives a worm wheel of said support axle and bearing set to obtain an azimuth motion.

9. The solar tracker according to claim 1,
wherein said support axle and bearing set is driven by said motorgear reducer and worm gear set through a worm wheel to obtain an azimuth motion of said support structure.

10. The solar tracker according to claim 1,
wherein said regular seat has four extension feet;
wherein said four extension feet are connected with a round track; and
wherein support wheels of said support structure moves a long said round track.
